(19) United States
(12) Patent Application Publication
(10) Pub. No.: US 2026/0140150 A1
(43) Pub. Date: May 21, 2026

(54) ANOMALY DETECTION METHOD, ANOMALY DETECTION SYSTEM, SENSOR AND ELECTRONIC DEVICE

(71) Applicant: Asahi Kasei Microdevices Corporation, Tokyo (JP)

(72) Inventor: Kenji KURIYAMA, Tokyo (JP)

(21) Appl. No.: 19/373,670

(22) Filed: Oct. 29, 2025

(30) Foreign Application Priority Data
Nov. 19, 2024 (JP) 2024-201817
Sep. 18, 2025 (JP) 2025-154679

(51) Int. Cl. G01R 19/165; G01R 19/00; G01R 19/10

(52) U.S. Cl. CPC G01R 19/16528; G01R 19/0069; G01R 19/10; G01R 19/16504

(57) ABSTRACT

Provided is an anomaly detection method for detecting an anomaly of a plurality of sensors, each packaged separately, using a plurality of comparators, the plurality of sensors respectively having a sensor element for detecting current or magnetism, a signal processing circuit for processing the detection signal from the sensor element, and an input terminal into which the detection signal from another sensor among the plurality of sensors is input, the plurality of comparator each corresponding to the plurality of sensors, comparing the detection signal output from a signal processing circuit of the corresponding sensor to a detection signal from another sensor, the method including comparing the detection signal from the corresponding sensor to the detection signal from another sensor and outputting an anomaly signal when the comparison result between the detection signal from the correspond sensor and the detection signal from another sensor does not meet a predetermined standard.

The contents of the following patent application(s) are incorporated herein by reference:

NO. 2024-201817 filed in JP on November 19, 2024

NO. 2025-154679 filed in JP on September 18, 2025.

### BACKGROUND

### 1. TECHNICAL FIELD

The present invention relates to an anomaly detection method, an anomaly detection system, a sensor, and an electronic device.

### 2. RELATED ART

Patent Document 1 describes that “the comparator 320 can compare the input signal and the threshold to sense the anomaly of the output from the magnetic sensor element 210 (0052).”

### RELATED ART DOCUMENTS

### PATENT DOCUMENTS

Patent Document 1: Japanese Patent Application Publication No. 2017-215307

### BRIEF DESCRIPTION OF THE DRAWINGS

FIG. 1 illustrates a configuration example of an anomaly detection system 11 in accordance with a first embodiment.

FIG. 2 illustrates a configuration example of an anomaly detection system 12 in accordance with a second embodiment.

FIG. 3 illustrates a configuration example of an anomaly detection system 13 in accordance with a third embodiment.

FIG. 4 illustrates a configuration example of an electronic device 20.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

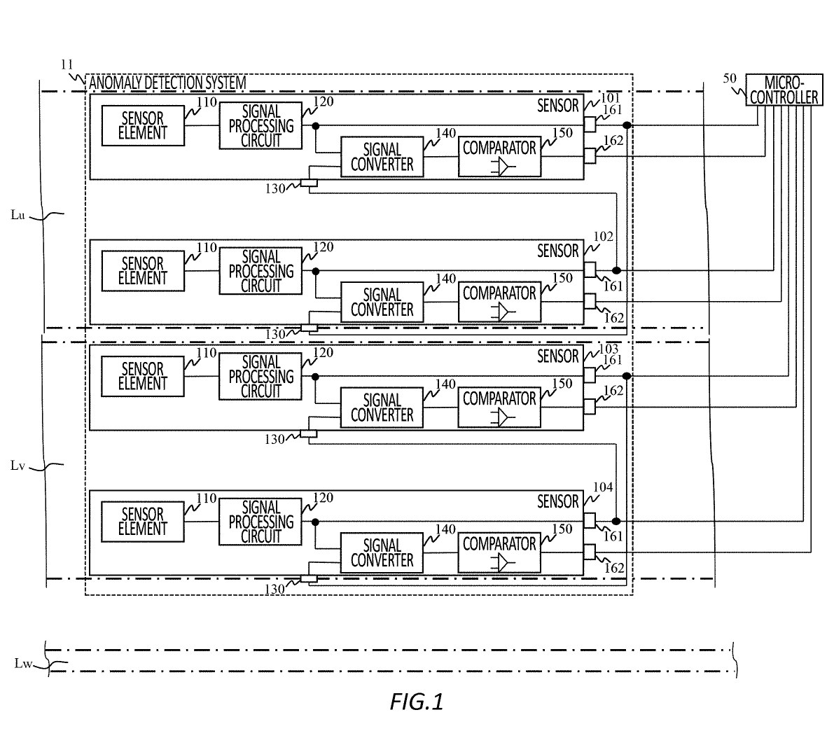

FIG. 1 illustrates a configuration example of an anomaly detection system 11 in accordance with a first embodiment. The anomaly detection system 11 includes a plurality of sensors 101, 102, 103, 104, each of which is packaged separately, and uses a plurality of comparators 150 to detect an anomaly of the sensor 101 and the like. In FIG. 1, the anomaly detection system 11 is indicated with a dashed line frame. The same applies to the following figures, and the redundant description will be omitted.

In the present embodiment, the anomaly detection system 11 inputs a detection signal of current or magnetism from the sensor 101 and the like to a microcontroller 50. In response to the detection signal from the sensor 101 and the like of the anomaly detection system 11, the microcontroller 50 performs feedback control on a device or the like connected to the microcontroller 50. The anomaly detection system 11 also inputs an anomaly signal from the sensor 101 and the like to the microcontroller 50.

The control target of the microcontroller 50 may be a motor, an actuator, a mobile stage, an engine, or the like, as long as it is a device that is controlled according to the detection signal from the sensor 101 and the like. In the present embodiment, the microcontroller 50, which is connected to a three-phase motor M via an inverter circuit or the like, uses a control signal depending on the detection signal from the sensor 101 and the like to control the inverter circuit, thereby controlling drive of the three-phase motor M. In response to the anomaly signal from the sensor 101 and the like of the anomaly detection system 11 being input, the microcontroller 50 may adjust the control of the three-phase motor M or the like, for example, may perform protection control such that excessive current does not flow into the three-phase motor M or the like or may stop or interrupt the control of the three-phase motor M or the like.

In the anomaly detection system 11 of the present embodiment, two of the sensor 101 and the like are arranged on each of current paths for any two phases among the current paths Lu, Lv, and Lw connected to each phase of U-phase, V-phase, and W-phase of a three-phase AC circuit C for supplying driving current to the three-phase motor M. The current paths Lu, Lv, Lw for the three phases are the current paths that electrically connect the three-phase motor M to the three-phase AC circuit C and supply the driving current from the three-phase AC circuit C to the three-phase motor M. The anomaly detection system 11 uses a plurality of comparators 150 to cause the two of the sensor 101 and the like for each phase to diagnose a state of each other and to output the anomaly signal described above when an anomaly is detected. More specifically, as one example, the anomaly detection system 11 causes the sensor 101 and the sensor 102 arranged on the current path Lu of the U-phase to diagnose the state of each other, and causes the sensor 103 and the sensor 104 arranged on the current path Lv of the V-phase to diagnose the state of each other. The anomaly detection system 11 is sometimes referred to as a two-phase duplex anomaly detection system. In FIG. 1, only parts of the current paths Lu, Lv, and Lw are respectively indicated with dashed-dotted lines and portions connected to a power supply, the three-phase motor M, or the like are omitted by wave lines. In addition, merely for clarity of description, the current paths Lu, Lv, and Lw are indicated with different thickness. The same applies to the following figures, and the redundant description will be omitted.

Each of the plurality of sensor 101 and the like in the present embodiment includes a sensor element 110, a signal processing circuit 120, an input terminal 130, a signal converter 140, a comparator 150, a first output terminal 161, and a second output terminal 162. The sensor 101 and the like may not include the signal converter 140. In the present embodiment, although each of the plurality of sensor 101 and the like is configured to include the comparator 150 within a package as one example, each comparator 150 may instead be provided separately from each of the sensor 101 and the like. In either case, the comparator 150 is provided for each of the sensor 101 and the like. In other words, the comparator 150 may correspond to each of the plurality of sensors 101 and may be external to the sensor 101.

The sensor element 110 detects current or magnetism. The sensor element 110 may be a resistance detection type current sensor for detecting current or may be a magnetic field detection type current sensor for detecting a magnetic field. In the present embodiment, the sensor element 110 is a magnetic field detection type current sensor, for example, a Hall element, a magneto-resistance element, or the like.

The sensor element 110 in the present embodiment measures the magnetic field generated by the current flowing through the current path Lu or the like. More specifically, the sensor element 110 outputs the detection signal with the voltage proportional to the magnetic field generated by the current flowing through the current path Lu or the like, that is, the voltage proportional to the amount of the current flowing through the current path Lu or the like. In the anomaly detection system 11 of the present embodiment, the sensor element 110 of each of the sensors 101, 102 outputs the detection signal with the voltage proportional to the amount of the current flowing through the current path Lu and the sensor element 110 of each of the sensors 103, 104 outputs the detection signal with the voltage proportional to the amount of the current flowing through the current path Lv. In the present embodiment, although the sensor element 110 is configured to measure the magnetic field generated by the current flowing through the current path Lu or the like as one example, the target for which the current or magnetic field is detected is not limited to the magnetic field generated by the current flowing through the current path Lu. For example, the sensor element 110 may detect the magnetic field generated by the magnetic field source other than the current path Lu, and may use the resistance detection type current sensor to directly detect the current flowing through the current path Lu.

The signal processing circuit 120 processes the detection signal from the sensor element 110. For example, the signal processing circuit 120 may reduce or remove an offset signal inherent in an element, which may be included in the detection signal from the sensor element 110, by a spinning current method, filtering, or the like, or may amplify the intensity of the detection signal. The processed detection signal output from the signal processing circuit 120 is transmitted from the first output terminal 161 to the microcontroller 50 and is also input to the signal converter 140.

The detection signal from another sensor 101 and the like among the plurality of sensor 101 and the like is input to the input terminal 130. In the present embodiment, the detection signal from the sensor 102, which measures, together with the sensor 101, the magnetic field generated by the current flowing through the current path Lu, is input to the input terminal 130 of the sensor 101, while the detection signal from the sensor 101 is input to the input terminal 130 of the sensor 102. The detection signal from the sensor 104, which measures, together with the sensor 103, the magnetic field generated by the current flowing through the current path Lv, is input to the input terminal 130 of the sensor 103, while the detection signal from the sensor 103 is input to the input terminal 130 of the sensor 104.

For the comparator 150 to compare the detection signal output from the signal processing circuit 120 to the detection signal from another sensor 101 and the like input from the input terminal 130, the signal converter 140 performs signal processing on the detection signal output from the signal processing circuit 120 and the detection signal from the other sensor 101 and the like. For example, the signal converter 140 respectively shifts the voltage of the detection signal output from the signal processing circuit 120 and the voltage of the detection signal from the other sensor 101 and the like input from the input terminal 130 to a predetermined voltage level. In the following description, to distinguish between the detection signal output from the signal processing circuit 120, that is, the detection signal based on the sensor element 110 inside the sensor 101 and the like and the detection signal based on the sensor element 110 external to the sensor 101 and the like, the former is sometimes referred to as self-detection signal and the latter is sometimes referred to as other detection signal. The signal converter 140 inputs the self-detection signal and the other detection signal, with the voltage level shifted, to the comparator 150.

The comparator 150 compares the self-detection signal to the other detection signal. The comparator 150 outputs an anomaly signal when the comparison result of the self-detection signal and the other detection signal does not meet a predetermined standard.

In the present embodiment, the comparator 150 of the sensor 101 compares the detection signal from the sensor element 110 of the sensor 101 to the detection signal from the sensor element 110 of the sensor 102, and outputs the anomaly signal when these comparison results do not meet the standard. More specifically, the comparator 150 of the sensor 101 calculates the difference or sum of these two detection signals, and outputs the anomaly signal when the difference or sum does not meet the standard.

For example, the comparator 150 may determine whether or not the difference between the voltage values of these two detection signals is 0, and output the anomaly signal when it is not 0, or may determine whether or not the difference is greater than a predetermined range, and output the anomaly signal when it is greater than the range. For example, when being set or arranged such that the polarity of one of these two detection signals is opposite, the comparator 150 may determine whether or not the sum of the voltage values of these two detection signals is 0, and output the anomaly signal when it is not 0, or may determine whether or not the sum is greater than a predetermined range, and output the anomaly signal when it is greater than the range.

In this case, the comparators 150 of the sensor 101 and the comparator 150 of the sensor 102 output the same signal. However, when any one of the comparators 150 has a failure, it outputs a different signal. Therefore, when the comparator 150 of the sensor 101 and the comparator 150 of the sensor 102 match at the anomaly signal, the microcontroller 50 as a determiner determines that the sensor element 110 or the signal processing circuit 120 has an anomaly and that the signal from the sensor 101 and the like cannot be used for control. On the other hand, when the output from the comparator 150 of the sensor 101 and the output from the comparator 150 of the sensor 102 do not match or match at the normal signal, the microcontroller 50 as the determiner continues to perform control by using the signal from the sensor 101 and the like.

The anomaly signal output from the comparator 150 is transmitted from the second output terminal 162 to the microcontroller 50. Each comparator 150 of the sensors 102, 103, 104 functions similarly to the comparator 150 of the sensor 101 and therefore the redundant descriptions will be omitted.

It is noted that, in the plurality of sensor 101 and the like, each of which is packaged separately, the sensor element 110, the signal processing circuit 120, and the like are formed as discrete electronic circuit elements or some of those are formed together as an IC on the semiconductor substrate and they are encapsulated with insulating resin with the terminals exposed. It is noted that each of the sensor element 110, the signal processing circuit 120, the signal converter 140, and the comparator 150 included in the sensor 101 and the like may be supplied with electric power from a common power supply or may be supplied with electric power from separate power supplies.

The configuration of the anomaly detection system 11 in accordance with the present embodiment has been described above with reference to FIG. 1. A first comparative example with respect to the anomaly detection system 11 of the present embodiment assumes a system which inputs a detection signal from a plurality of sensors to the diagnoser included in the microcontroller and causes the diagnoser to perform anomaly diagnosis of the plurality of sensors. In the system of the first comparative example, the diagnoser of the microcontroller needs a high reliability, and the load of failure diagnosis in the microcontroller is heavy.

In addition, in the system of the first comparative example, although the microcontroller diagnoses whether each sensor is normal or abnormal based on the detection signal from each sensor, reliably preventing misdiagnosis requires the redundancy of the microcontroller or the redundancy of the diagnosis process in the microcontroller, increasing the number of parts or increasing the burden of the microcontroller.

A second comparative example with respect to the anomaly detection system 11 in the present embodiment assume a system where only a particular sensor among the plurality of sensors, for example, only one of a pair of sensors, is provided with a comparator, the comparator compares a detection signal from the particular sensor to a predetermined reference value, and the anomaly diagnosis result of the particular sensor is considered as the overall anomaly diagnosis result of the plurality of sensors. Since the system of the second comparative example cannot detect the anomaly of the sensors among the plurality of sensors where the comparator is not provided, the overall anomaly diagnosis result of the plurality of sensors is unreliable. In addition, when there is only one comparator, it is not known whether the comparator has a failure, and it is also not known whether or not the anomaly diagnosis result is correct.

A third comparative example with respect to the anomaly detection system 11 in the present embodiment assumes a system where all of the plurality of sensors are provided with two sets of the sensor element and the signal processing circuit, and are further provided with the comparator for comparing the two sets of the detection signals, and each sensor performs self-diagnosis for the presence or absence of an anomaly. Each sensor in the system of the third comparative example has a large circuit scale.

Meanwhile, the anomaly detection system 11 of the present embodiment includes a plurality of sensors 101, 102, 103, 104, each of which is packaged separately, and each of the plurality of sensor 101 and the like has a sensor element 110 for detecting current or magnetism, a signal processing circuit 120 for processing the detection signal from the sensor element 110, an input terminal 130 into which the detection signal is input from another sensor 102 and the like among the plurality of sensor 101 and the like, and a comparator 150 for comparing the self-detection signal output from the signal processing circuit 120 to the detection signal from the other sensor 102 and the like. The anomaly detection system 11 including such a configuration compares the self-detection signal and the detection signals from the other sensor 102 and the like in each comparator 150 of the plurality of sensor 101 and the like and outputs the anomaly signal when the comparison result of the self-detection signal and the detection signals of the other sensor 102 and the like does not meet a predetermined standard. In other words, each of the plurality of sensor 101 and the like uses the self-detection signal and the detection signals from the other sensor 102 and the like to perform mutual diagnosis. Furthermore, in other words, two or more sensors 101 perform mutual diagnosis with each other.

Comparing the anomaly detection system 11 in the present embodiment to the system in the first comparative example, the system in the first comparative example causes the microcontroller to perform anomaly diagnosis for the plurality of sensors, while the anomaly detection system 11 in the present embodiment does not cause the microcontroller 50 to perform the anomaly diagnosis but causes the two or more sensors 101 to perform mutual diagnosis with each other, which can ensure redundancy independent of the microcontroller 50. According to the anomaly detection system 11 in the present embodiment, the anomaly detection can be performed on the side of the sensor 101 and the like, and thus the microcontroller 50 may perform determination based on the diagnosis result. In addition, the diagnosis function of the microcontroller 50 can also be utilized together with the sensor 101 and the like to make the diagnosis redundant, which can further improve the reliability of the determination and can also reduce the load of the microcontroller 50. In addition, since misdiagnosis can be avoided even when the comparator 150 has an anomaly, the microcontroller 50 only has to perform determination based on the diagnosis result of the sensor 101 and the like without performing anomaly diagnosis, which can reduce the load of the microcontroller 50.

Comparing the anomaly detection system 11 in the present embodiment to the system in the second comparative example, the system in the second comparative example has a configuration where only a particular sensor among the plurality of sensors is provided with a comparator, the comparator compares the detection signal from the particular sensor to a predetermined reference value, and the anomaly diagnosis result of the particular sensor is considered as the overall anomaly diagnosis result of the plurality of sensors. Meanwhile, in the anomaly detection system 11 in the present embodiment, each of the plurality of sensor 101 and the like uses the self-detection signal and the detection signals from the other sensor 102 and the like to perform mutual diagnosis. In this way, according to the anomaly detection system 11 in the present embodiment, since any of the sensor 101 and the like are not provided with the comparator for comparing the self-detection signal to the predetermined reference value, the circuit scale of each sensor 101 and the like can be reduced, and thus the incidence of failure can be reduced. Furthermore, according to the anomaly detection system 11 in the present embodiment, since all of the plurality of sensor 101 and the like perform the mutual diagnosis, the overall anomaly diagnosis result of the plurality of sensor 101 and the like is reliable.

Comparing the anomaly detection system 11 in the present embodiment to the system in the third comparative example, in the system in the third comparative example, all of the plurality of sensors are provided with two sets of the sensor element and the signal processing circuit and are further provided with the comparator for comparing the two sets of detection signals, so that each sensor performs self-diagnosis for the presence or absence of an anomaly. Meanwhile, in the anomaly detection system 11 in the present embodiment, each of the plurality of sensor 101 and the like is provided with one set of the sensor element 110 and the signal processing circuit 120 and is provided with the comparator for comparing the self-detection signal to the detection signals from the other sensor 102 and the like input from the input terminal 130, so that the plurality of sensor 101 and the like perform mutual diagnosis. In this way, according to the anomaly detection system 11 in the present embodiment, the circuit scale of each sensor 101 and the like can be reduced, which allows the incidence of failure to be reduced.

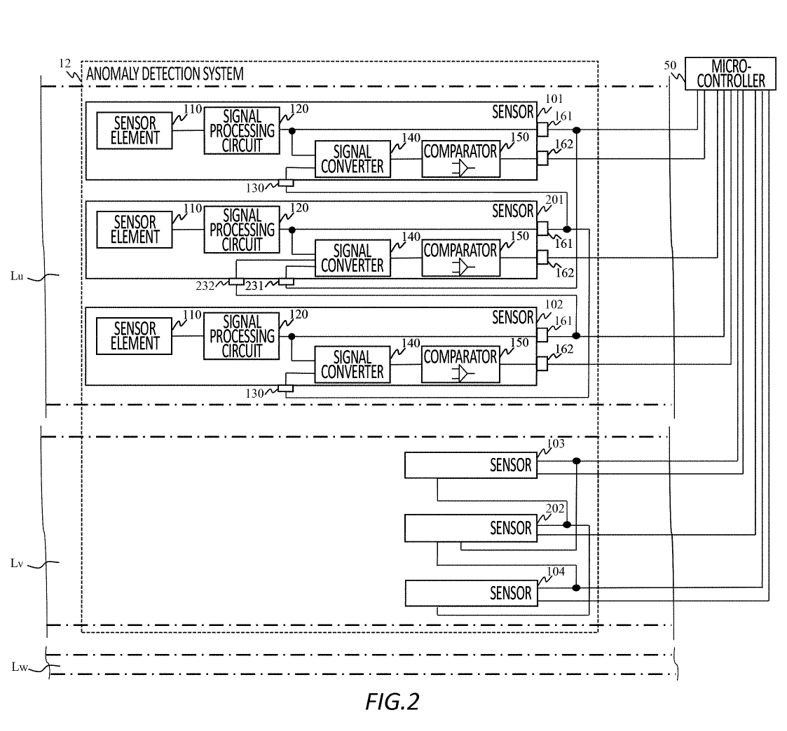

FIG. 2 illustrates a configuration example of the anomaly detection system 12 in accordance with the second embodiment. Unlike the anomaly detection system 11 in accordance with the first embodiment, the anomaly detection system 12 in accordance with the second embodiment arranges three sensor 101 and the like for the current path for any one phase. More specifically, as one example, the anomaly detection system 12 arranges a sensor 201 in addition to the sensor 101 and the sensor 102 on the current path Lu of the U-phase and arranges a sensor 202 in addition to the sensor 103 and the sensor 104 on the current path Lv of the V-phase.

The anomaly detection system 12 causes three sensor 101 and the like for each phase to diagnose the state of each other and to output an anomaly signal when an anomaly is detected. More specifically, the anomaly detection system 12 causes the two sensors 101 and 201 arranged on the current path Lu of the U-phase to diagnose the state of each other and causes the two sensors 102 and 201 arranged on the current path Lu of the U-phase to diagnose the state of each other. The anomaly detection system 12 also causes the sensor 103 and the sensor 202 arranged on the current path Lv of the V-phase to diagnose the state of each other, and causes the sensor 104 and the sensor 202 arranged on the current path Lv of the V-phase to diagnose the state of each other.

Unlike the sensor 101 and the like, the sensors 201, 202 have a first input terminal 231 and a second input terminal 232 instead of the input terminal 130. Since the other configuration in the sensors 201, 202 is the same as the corresponding configuration in the sensor 101 and the like, the same reference numerals as those for the corresponding configuration in the sensor 101 and the like are used and the redundant descriptions will be omitted.

The detection signal from the sensor 101 is input to the first input terminal 231 of the sensor 201. The detection signal from the sensor 102 is input to the second input terminal 232 of the sensor 201. For the sensor 202, which is similar to the sensor 201, the redundant description will be omitted, and the illustration of the detailed configuration will be omitted. It is noted that, in FIG. 2, since the sensors 103, 104 are also similar to the sensors 101, 102, the redundant description will be omitted, and the illustration of the detailed configuration will be omitted.

The comparator 150 of the sensor 201 compares the self-detection signal to the detection signal from the other sensor 101. The comparator 150 of the sensor 201 also compares the self-detection signal to the detection signal from the other sensor 102. The comparator 150 of the sensor 201 outputs an anomaly signal when the comparison result between the self-detection signal and the other detection signal does not meet a predetermined standard, with respect to each of these comparisons, that is, with respect to two combinations of the sensor 201 and each of the two sensors 101, 102. More specifically, similar to the comparator 150 of the sensor 101 and the like, the comparator 150 of the sensor 201 calculates the difference or sum of the two detection signals for each of these comparisons, and outputs the anomaly signal when the difference or sum does not meet the standard. A more specific example of the comparison in the comparator 150 of the sensor 201 may be similar to the comparison in the comparator 150 of the sensor 101 and the like, for example, the signal converter 140 generates a signal A obtained by doubling the detection signal from the sensor 201 and a signal B obtained as the sum of the detection signals from the sensors 101 and 102 and the comparator 150 obtains the difference between A and B, or the like, and the redundant description will be omitted.

Unlike the sensor 101 and the like, the sensor 201 is a sensor for comparison. More specifically, the processed detection signal output from the signal processing circuit 120 of the sensor 201 is input to each input terminal 130 of the sensor 101 and the sensor 102 without being transmitted from the first output terminal 161 to the microcontroller 50.

When the sensor 101 has an anomaly, the sensor 101 and the sensor 201 issue an anomaly alarm. When the sensor 102 has an anomaly, the sensor 102 and the sensor 201 issue an anomaly alarm. In addition, when the sensor 201 has an anomaly, the sensor 101, the sensor 102, and the sensor 201 issue an anomaly alarm. In this manner, the microcontroller 50 can identify a sensor with an anomaly based on the anomaly alarm state. Accordingly, the microcontroller 50 uses the signal from the sensor without any anomaly to continue the control of the system. If the three comparators 150 are normal, they all output the same output (the diagnosis result), but when a comparator has a failure, the only diagnosis result of the comparator issues the anomaly alarm, which allows the failure of the comparator to be known. At this time, the microcontroller 50 determines that the anomaly is not for the sensor element 110 and the signal processing circuit 120, and uses the signal from the sensor 101 or the sensor 102 to continue the control of the system.

The configuration of the anomaly detection system 12 in accordance with the present embodiment has been described above with reference to FIG. 2. Since the anomaly detection system 12 in accordance with the present embodiment can identify a sensor having an anomaly with one phase and can also use the remaining normal sensors to continue the system operation, it has effects similar to or more than those of the anomaly detection system 11 in accordance with the first embodiment.

According to the anomaly detection system 12 in accordance with the present embodiment, as described above, the three sensor 101 and the like are arranged on the current path for one phase and each of the three sensor 101 and the like outputs the detection signal with a voltage proportional to the amount of the current flowing through the current path. As for the three sensors 101, 102, 201 arranged on the current path Lu, the detection signal from the sensor 201 is not input to the microcontroller 50, and the detection signals from the sensor 101 and the sensor 102 are input to the microcontroller 50. On the other hand, the anomaly signals that are not only from the sensor 101 and the sensor 102 but also from the sensor 201 are input from each comparator 150 through the second output terminal 162 to the microcontroller 50. Therefore, in the present embodiment, the microcontroller 50 may identify which of the three sensors 101, 102, 201 has an anomaly based on which of the three sensors 101, 102, 201 has output the anomaly signal.

For example, when only the sensor 101 among the three sensors 101, 102, 201 has an anomaly, the anomaly signal is output from the sensor 101 and the sensor 201 and is not output from the sensor 102, which allows only the sensor 101 to be identified as having an anomaly. For example, when only the sensor 102 among the three sensors 101, 102, 201 has an anomaly, the anomaly signal is output from the sensor 102 and the sensor 201 and is not output from the sensor 101, which allows only the sensor 102 to be identified as having an anomaly. For example, when only the sensor 201 among the three sensors 101, 102, 201 has an anomaly, or when at least two sensors among the three sensors 101, 102, 201 have an anomaly, the anomaly signals are output from all of the three sensors 101, 102, 201, which allows for determination that only one of the two sensors 101, 102 has no anomaly and allows for identification that only the sensor 201 has an anomaly or at least two sensors among the three sensors 101, 102, 201 have an anomaly.

When only one of the two sensors 101, 102 is identified as having an anomaly, the microcontroller 50 can use the detection signals from the other of the two sensors 101, 102 and the sensor 201 to continue to control the drive of the three-phase motor M. In addition, when only one of the two sensors 101, 102 has been identified as having an anomaly, the microcontroller 50 can notify the user that only one of them needs to be exchanged.

Furthermore, this detection method can be applied not only to the phase current detection for three-phase motors but also to the anomaly detection in the case where the plurality of sensor 101 and the like are used. Also in the present embodiment, the microcontroller 50 itself does not need to perform anomaly diagnosis and only has to perform determination based on the anomaly diagnosis result of the sensor 101 and the like, thus allowing the load of the microcontroller 50 to be reduced.

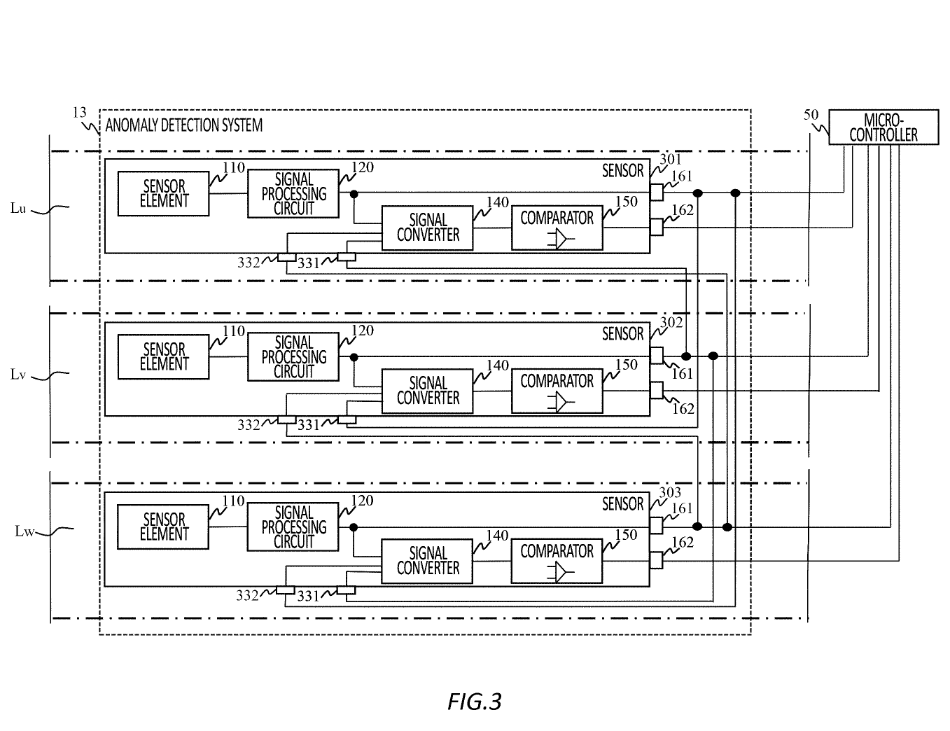

FIG. 3 illustrates a configuration example of the anomaly detection system 13 in accordance with a third embodiment. Unlike the anomaly detection system 11 in accordance with the first embodiment, the anomaly detection system 13 in accordance with the third embodiment arranges three sensor 301 and the like, one for each current path for three phases. More specifically, the anomaly detection system 13 arranges the sensor 301 on the current path Lu of the U-phase, arranges the sensor 302 on the current path Lv of the V-phase, and arranges the sensor 303 on the current path Lw of W-phase.

The anomaly detection system 13 causes the three sensor 301 and the like arranged for each of the three phases to diagnose the state of each other and to output an anomaly signal when an anomaly is detected. Such an anomaly detection system 12 is sometimes referred to as a three-phase simplex anomaly detection system.

Unlike the sensor 101 and the like in the first embodiment, the sensors 301, 302, 303 have a first input terminal 331 and a second input terminal 332 instead of the input terminal 130. Since the other configurations in the sensors 301, 302, 303 are the same as the corresponding configurations in the sensor 101 and the like, the same reference numerals as the corresponding configurations in the sensor 101 and the like will be used, and the redundant descriptions will be omitted.

Unlike the sensor 201 and the like in the second embodiment, the sensor 301 and the like are not sensors for comparison. In other words, the processed detection signal output from the signal processing circuit 120 of the sensor 301 and the like is transmitted from the first output terminal 161 to the microcontroller 50 and also input to the first input terminal 331 and the second input terminal 332 of each of the other two sensor 302 and the like.

The detection signal from the sensor 302 is input to the first input terminal 331 of the sensor 301. The detection signal from the sensor 303 is input to the second input terminal 332 of the sensor 301. Since the sensors 302, 303 are similar to the sensor 301, the redundant description will be omitted.

The comparator 150 of the sensor 301 compares the self-detection signal to the detection signals from the other two sensors 302, 303. More specifically, the comparator 150 of the sensor 301 calculates the sum of the three detection signals, which are the self-detection signal and the detection signals from the other two sensors 302, 303, and outputs an anomaly signal when the sum does not fall within a predetermined range.

For example, the comparator 150 of the sensor 301 may determine whether or not the sum of the voltage values of these three detection signals corresponds to 0 A and, when it does not correspond to 0 A, output an anomaly signal, or may determine whether or not the sum is greater than a predetermined range and, when it is greater than the range, output an anomaly signal.

The three comparators 150 of the sensors 301, 302, 303 output the same signals. However, when any of the comparators 150 has a failure, it may output a signal different from those of the two comparators 150 that are normal. Therefore, the microcontroller 50 uses the present configuration to determine the presence or absence of an anomaly of the comparator 150 and can use the normal comparator 150 to continue the anomaly diagnosis.

The configuration of the anomaly detection system 13 in accordance with the present embodiment has been described above with reference to FIG. 3. The anomaly detection system 13 in accordance with the present embodiment has a similar effect to the anomaly detection system 11 in accordance with the first embodiment.

According to the anomaly detection system 13 in accordance with the present embodiment, as described above, one of the sensor 301 and the like is arranged for each of the current paths for three phases and the detection signal with the voltage proportional to the amount of the current flowing through each of the current paths for three phases is output from each of the three sensor 301 and the like. In this manner, the anomaly detection system 13 can utilize the fact that the sum of the currents for three phases is 0 A to perform mutual diagnosis using the three sensor 301 and the like to determine whether the sum of the detection signals from the three sensors 301, 302, 303 corresponds to 0 A.

Also in the anomaly detection system 13 in accordance with the present embodiment, since the anomaly of a main circuit consisting of the sensor element 110 and the signal processing circuit 120 and the anomaly of the comparator 150 can be distinguished, the microcontroller 50 itself does not need to perform the anomaly diagnosis and only has to perform determination based on the anomaly diagnosis result of the sensor 101 and the like, which can reduce the load of the microcontroller 50.

The anomaly detection system described in the above-described plurality of embodiments may be applicable to a two-phase AC circuit and a single-phase AC circuit in addition to the three-phase AC circuit. In the two-phase AC circuit, one sensor is arranged on each of the current paths for two phases and the two sensors may utilize the fact that the sum of the amount of the two-phase currents is 0 A to perform mutual diagnosis to determine whether the sum of the outputs from the two sensors corresponds to 0 A.

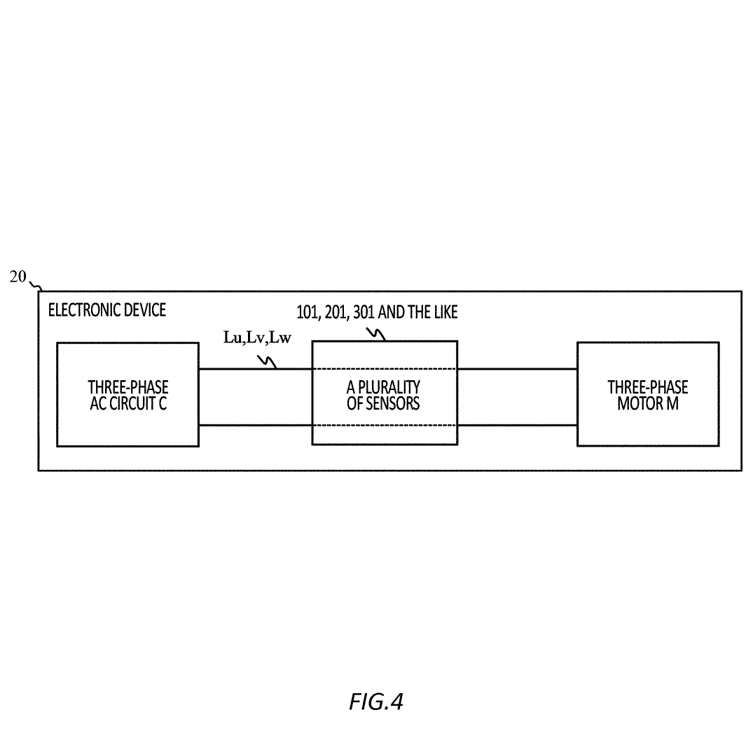

FIG. 4 illustrates a configuration example of the electronic device 20. The electronic device 20 includes the three-phase motor M, the three-phase AC circuit C, the current paths Lu, Lv, Lw for three phases electrically connecting the three-phase motor M and the three-phase AC circuit C, the plurality of sensors 101, 201, 301, and the like, which are described using FIG. 1 to 3. In one example of the electronic device 20, two or more of the plurality of sensors 101, 201, 301, and the like may be arranged for the current path Lu and the like for one phase among the current path Lu and the like for three phases, as in the plurality of sensors 101, 102, 103, 104 in the anomaly detection system 11 in accordance with the first embodiment and the plurality of sensors 101, 102, 103, 104, 201, 202 and the like in the anomaly detection system 12 in accordance with the second embodiment. In another one example of the electronic device 20, like the plurality of sensors 301, 302, 303 in accordance with the third embodiment, three sensors among the plurality of sensors 101, 201, 301, and the like may be arranged, one for each current path Lu and the like for three phases. The electronic device 20 may further include the microcontroller 50 described above, and the electronic device 20 and the microcontroller 50 may be separate ones and cooperate with each other. The electronic device 20 in this example also has a similar effect to the anomaly detection system 11, 12, 13 in accordance with the plurality of embodiments described above.

While the embodiments of the present invention have been described, the technical scope of the present invention is not limited to the above-described embodiments. It is apparent to persons skilled in the art that various alterations or improvements can be added to the above-described embodiments. It is also apparent from the description of claims that the embodiments added with such alterations or improvements can be included in the technical scope of the present invention.

The operations, procedures, steps, and stages or the like of each process performed by an apparatus, system, program, and method shown in the claims, specification, or drawings can be performed in any order as long as the order is not indicated by "prior to," "before," or the like and as long as the output from a previous process is not used in a later process. Even if the process flow is described using phrases such as "first" or "next" in the claims, specification, and drawings, it does not necessarily mean that the process must be performed in this order.

### EXPLANATION OF REFERENCES

C three-phase AC circuit;

M three-phase motor;

Lu, Lv, Lw current path;

11 anomaly detection system;

50 microcontroller;

101, 102, 103, 104 sensor;

110 sensor element;

120 signal processing circuit;

130 input terminal;

140 signal converter;

150 comparator;

161 first output terminal;

162 second output terminal;

12 anomaly detection system;

201, 202 sensor;

231 first input terminal;

232 second input terminal;

13 anomaly detection system;

301, 302, 303 sensor

331 first input terminal;

332 second input terminal;

20 electronic device.

What is claimed is:

1. An anomaly detection method for detecting an anomaly of a plurality of sensors, each of which is packaged separately, using a plurality of comparators, wherein
each of the plurality of sensors has a sensor element which detects current or magnetism, a signal processing circuit that processes a detection signal from the sensor element, and an input terminal into which a detection signal is input from another sensor among the plurality of sensors,
each of the plurality of comparators corresponds to each of the plurality of sensors and compares a detection signal output from the signal processing circuit of a corresponding sensor to a detection signal from the another sensor, and
the anomaly detection method comprises:
comparing the detection signal from the corresponding sensor to the detection signal from the another sensor; and
outputting an anomaly signal when a comparison result between the detection signal from the corresponding sensor and the detection signal from the another sensor does not meet a predetermined standard.

2. The anomaly detection method according to claim 1, further comprising
determining a failure mode of the plurality of sensors based on a combination pattern of output signals from the plurality of comparators and determining a control mode of the plurality of sensors according to the failure mode.

3. The anomaly detection method according to claim 1, wherein each of the plurality of sensors has a corresponding comparator, among the plurality of comparators, within a package.

4. The anomaly detection method according to claim 1, wherein two sensors, each being identical to the sensor, are arranged for a current path for one phase,
the comparing includes, for the two sensors, comparing the detection signal from the corresponding sensor to the detection signal from the another sensor, and
the outputting includes, for the two sensors, outputting the anomaly signal when the comparison result does not meet the standard.

5. The anomaly detection method according to claim 4, wherein the comparing includes, for the two sensors, calculating a difference or sum of the detection signal from the corresponding sensor and the detection signal from the another sensor, and
the outputting includes, for the two sensors, outputting the anomaly signal when the difference or the sum, as the comparison result, does not meet the standard.

6. The anomaly detection method according to claim 1, wherein three sensors, each being identical to the sensor, are arranged for a current path for one phase,
the comparing includes, for two sensors among the three sensors, comparing the detection signal from the corresponding sensor to the detection signal from the another sensor, and
the outputting includes, for the two sensors, outputting the anomaly signal when the comparison result does not meet the standard.

7. The anomaly detection method according to claim 6, wherein one of the three sensors is a sensor for comparison,
the comparing includes, for two combinations of the sensor for comparison and each of remaining two sensors among the three sensors, comparing the detection signal from the corresponding sensor to the detection signal from the another sensor,
the outputting includes, for the two combinations, outputting the anomaly signal when the comparison result does not meet the standard, and
the anomaly detection method further comprises identifying which of the three sensors has an anomaly based on which of the three sensors the anomaly signal is output from.

8. The anomaly detection method according to claim 1, wherein three sensors, being identical to the sensor, are arranged, one for each current path for three phases in a three-phase AC circuit,
in each of the three sensors, detection signals from other two sensors are input to the input terminal and a corresponding comparator among the plurality of comparators compares the detection signal from the corresponding sensor to detection signals from the other two sensors,
the comparing includes, for the three sensors, calculating a sum of the detection signal from the corresponding sensor and the detection signals from the other two sensors, and
the outputting includes, for the three sensors, outputting the anomaly signal when the sum, as the comparison result, does not fall within a predetermined range as the standard.

9. The anomaly detection method according to claim 1, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

10. The anomaly detection method according to claim 2, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

11. The anomaly detection method according to claim 3, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

12. The anomaly detection method according to claim 4, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

13. The anomaly detection method according to claim 5, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

14. The anomaly detection method according to claim 6, wherein each of the plurality of sensors further has a signal converter which performs signal processing of the detection signal from the corresponding sensor and the detection signal from the another sensor in order for a corresponding comparator among the plurality of comparators to compare the detection signal from the corresponding sensor to the detection signal from the another sensor, and
before the comparing, the anomaly detection method further comprising performing the signal processing of the detection signal from the corresponding sensor and the detection signal from the another sensor.

15. The anomaly detection method according to claim 9, wherein the signal processing includes respectively shifting a voltage of the detection signal from the corresponding sensor and a voltage of the detection signal from the another sensor to a predetermined voltage level.

16. An anomaly detection system which detects an anomaly of a plurality of sensors, each of which is packaged separately, using a plurality of comparators, wherein
the anomaly detection system comprises the plurality of sensors and the plurality of comparators,
each of the plurality of sensors has a sensor element which detects current or magnetism, a signal processing circuit which processes a detection signal from the sensor element, and an input terminal into which a detection signal is input from another sensor among the plurality of sensors, and
each of the plurality of comparators corresponds to each of the plurality of sensors, compares a detection signal output from the signal processing circuit of a corresponding sensor to a detection signal from the another sensor, and outputs an anomaly signal when a comparison result thereof does not meet a predetermined standard.

17. The anomaly detection system according to claim 16, further comprising a determination unit which determines a failure mode of the plurality of sensors based on a combination pattern of output signals from the plurality of comparators and determines a control mode for the plurality of sensors according to the failure mode.

18. A packaged sensor, comprising:
a sensor element which detects current or magnetism;
a signal processing circuit which processes a detection signal from the sensor element;
an input terminal into which a detection signal from another packaged sensor is input; and
a comparator which compares a self-detection signal output from the signal processing circuit to a detection signal from the another packaged sensor and outputs an anomaly signal when a comparison result thereof does not meet a predetermined standard.

19. An electronic device, comprising a three-phase motor, a three-phase AC circuit, current paths for three phases electrically connecting the three-phase motor and the three-phase AC circuit, and the sensor according to claim 18, wherein
two or more sensors, each being identical to the sensor, are arranged for a current path for one phase among the current paths for three phases.

20. An electronic device, comprising a three-phase motor, a three-phase AC circuit, current paths for three phases electrically connecting the three-phase motor and the three-phase AC circuit, and the sensor according to claim 18, wherein
three sensors, each being identical to the sensor, are arranged, one for each current path for the three phases.
